(19) United States
(12) Patent Application Publication
(10) Pub. No.: US 2016/0027512 A1
(43) Pub. Date: Jan. 28, 2016

(54) NONVOLATILE SEMICONDUCTOR MEMORY DEVICE AND OPERATION METHOD OF THE SAME

(71) Applicant: Kabushiki Kaisha Toshiba, Minato-ku (JP)

(72) Inventors: Daisuke HAGISHIMA, Yokohama-shi (JP); Mitsutoshi Nakamura, Yokkaichi-shi (JP); Shigeo Kondo, Yokkaichi-shi (JP); Michiru Hogyoku, Yokkaichi-shi (JP)

(73) Assignee: Kabushiki Kaisha Toshiba, Minato-ku (JP)

(21) Appl. No.: 14/524,046

(22) Filed: Oct. 27, 2014

Related U.S. Application Data
(60) Provisional application No. 62/028,110, filed on Jul. 23, 2014.

(51) Int. Cl. G11C 16/10; G11C 16/26

(52) U.S. Cl. CPC G11C 16/10; G11C 16/26

(57) ABSTRACT

A nonvolatile semiconductor memory device according to an embodiment includes a control unit, during the read sequence performed to an interested cell, performing a first read operation to detect that a threshold voltage of an adjacent cell is higher than a second reference voltage higher, performing a second read operation to detect that the threshold voltage of the interested cell is higher than a first reference voltage while applying a first bit line voltage to the adjacent bit line when threshold voltages of the adjacent cells are lower than the second reference voltage, and to detect that the threshold voltage of the interested cell is higher than the first reference voltage while applying a second bit line voltage higher than the first bit line voltage to the adjacent bit line when threshold voltages of the adjacent cells are higher than the second reference voltage, after the first read operation.

This application is based upon and claims the benefit of priority from the prior U.S. Provisional Application 62/028,110, filed on Jul. 23, 2014, the entire contents of which are incorporated herein by reference.

### BACKGROUND

1. Field

The present disclosure relates to a nonvolatile semiconductor memory device and an operation method of the same.

2. Description of the Related Art

A NAND flash memory is well known as a nonvolatile, electrically-rewritable, highly-integrated semiconductor memory device. In the NAND flash memory, plural memory cells are connected in series while a source/drain diffusion layer is shared by the memory cells adjacent to each other, thereby forming a NAND string. Both ends of the NAND string are connected to a bit line and a source line through a select gate transistor, respectively. The configuration of the NAND string reduces a unit cell area to achieve mass storage compared with a NOR flash memory.

The memory cell of the NAND flash memory includes a floating gate (charge accumulation layer) that is formed on a semiconductor substrate with a tunnel insulating film interposed therebetween and a control gate that is stacked on the floating gate with an inter-gate insulating film interposed therebetween. In the memory cell, data is stored in a nonvolatile manner according to a charge accumulation state of the floating gate. For example, a low-threshold-voltage state in which electrons of the floating gate are emitted is set to data ‘1’, and binary data is stored. A threshold voltage distribution to be written is further fragmented to enable multi-level storage such as four-level storage and eight-level storage.

However, nowadays an interference effect between adjacent cells increases with increasing integration of the NAND flash memory, and it is becoming difficult to normally and finely write and read the data.

### BRIEF DESCRIPTION OF THE DRAWINGS

FIG. 1 is a block diagram illustrating a nonvolatile semiconductor memory device according to a first embodiment;

FIG. 2 is a circuit diagram illustrating a memory cell array of the nonvolatile semiconductor memory device of the first embodiment;

FIG. 3 is a structural diagram illustrating a memory cell of the nonvolatile semiconductor memory device of the first embodiment;

FIG. 4 is a view illustrating a state of a change in threshold voltage distribution of the memory cell during a write sequence in the nonvolatile semiconductor memory device of the first embodiment;

FIG. 5 is a view illustrating an L-page read step of a read sequence in a nonvolatile semiconductor memory device according to a comparative example;

FIG. 6 is a view illustrating a state of a read voltage during the L-page read step of the read sequence in the nonvolatile semiconductor memory device of the comparative example;

FIG. 7 is a view illustrating a bias state of the memory cell array during the L-page read step of the read sequence in the nonvolatile semiconductor memory device of the comparative example;

FIG. 8 is a view illustrating a U-page read step of the read sequence in the nonvolatile semiconductor memory device of the comparative example;

FIG. 9 is a flowchart illustrating the U-page read step of the read sequence in the nonvolatile semiconductor memory device of the comparative example;

FIG. 10 is a view illustrating the state of the read voltage during the U-page read step of the read sequence in the nonvolatile semiconductor memory device of the comparative example;

FIG. 11 is a view illustrating an interference effect generated between adjacent memory cells of the nonvolatile semiconductor memory device of the comparative example;

FIG. 12 is a view illustrating the state of the threshold voltage distribution of the memory cell after the write sequence of the nonvolatile semiconductor memory device of the comparative example;

FIG. 13 is a flowchart illustrating the U-page read step of the read sequence in the nonvolatile semiconductor memory device of the first embodiment;

FIG. 14 is a view illustrating the state of the read voltage during the U-page read step of the read sequence in the nonvolatile semiconductor memory device of the first embodiment;

FIG. 15 is a view illustrating the bias state of the memory cell array during the U-page read step of the read sequence in the nonvolatile semiconductor memory device of the first embodiment;

FIG. 16 is a graph illustrating a relationship between a bit line voltage at an adjacent bit line and a threshold voltage of an interested cell in the nonvolatile semiconductor memory device of the first embodiment;

FIG. 17 is a view illustrating the state of the threshold voltage distribution of the memory cell during the read sequence in the nonvolatile semiconductor memory device of the comparative example;

FIG. 18 is a view illustrating the state of the threshold voltage distribution of the memory cell during the read sequence in the nonvolatile semiconductor memory device of the first embodiment;

FIG. 19 is a view illustrating the state of the threshold voltage distribution of the memory cell during the read sequence in the nonvolatile semiconductor memory device of the first embodiment;

FIG. 20 is a view illustrating the state of the threshold voltage distribution of the memory cell during the read sequence in the nonvolatile semiconductor memory device of the first embodiment;

FIG. 21 is a flowchart illustrating a read sequence in a nonvolatile semiconductor memory device according to a second embodiment;

FIG. 22 is a flowchart illustrating another read sequence in the nonvolatile semiconductor memory device of the second embodiment; and

FIG. 23 is a flowchart illustrating still another read sequence in the nonvolatile semiconductor memory device of the second embodiment.

### DETAILED DESCRIPTION

A nonvolatile semiconductor memory device according to an exemplary embodiment includes: a memory cell array including a plurality of bit lines, a plurality of word lines and a source line that intersect the plurality of bit lines, and a plurality of memory strings that are provided between the bit line and the source line, each of the plurality of memory strings including a plurality of series-connected memory cells each of which is connected to the word line; and a control unit that performs a write sequence writing data to the memory cell and a read sequence reading data from the memory cell, wherein, assuming that the certain bit line is an interested bit line, that the bit line adjacent to the interested bit line is an adjacent bit line, that the certain memory cell belonging to the memory string between the interested bit line and the source line is an interested cell, and that the memory cell belonging to the memory string between the adjacent bit line and the source line and being commonly connected to the interested cell and the certain word line is an adjacent cell, the control unit causes a threshold voltage of the memory cell to transition to a desired value higher than a first reference voltage after causing the threshold voltage to transition to a value lower than the first reference voltage during the write sequence, the control unit, during the read sequence performed to the interested cell, performs a first read operation to detect that the threshold voltage of the adjacent cell is higher than a second reference voltage higher than the first reference voltage, performs a second read operation to detect that the threshold voltage of the interested cell is higher than the first reference voltage while applying a first bit line voltage to the adjacent bit line when threshold voltages of the adjacent cells are lower than the second reference voltage after the first read operation, and performs the second read operation to detect that the threshold voltage of the interested cell is higher than the first reference voltage while applying a second bit line voltage higher than the first bit line voltage to the adjacent bit line when the threshold voltages of the adjacent cells are higher than the second reference voltage after the first read operation.

Hereinafter, a nonvolatile semiconductor memory device according to an exemplary embodiment and an operation method of the same will be described with reference to the drawings.

### First Embodiment

An entire configuration of a nonvolatile semiconductor memory device according to a first embodiment will be described. A NAND flash memory is described below by way of example.

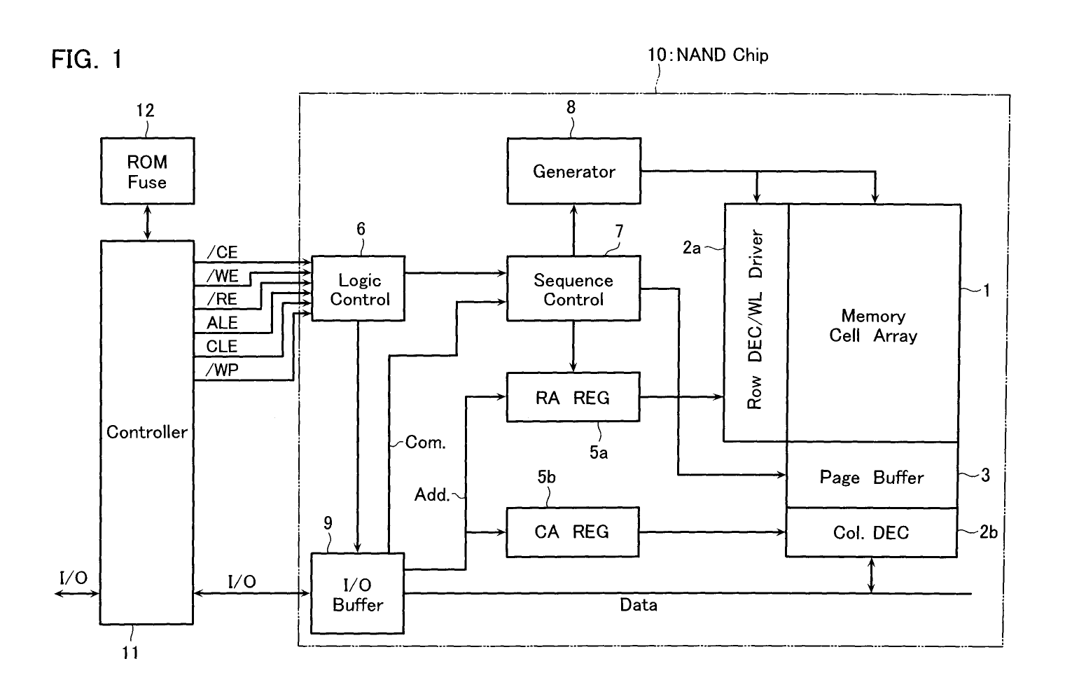

FIG. 1 is a block diagram of the nonvolatile semiconductor memory device of the first embodiment.

The flash memory in FIG. 1 includes a NAND chip 10, a controller 11 that controls the NAND chip 10, and a ROM fuse 12 in which various pieces of information necessary to access the NAND chip 10 are stored.

The NAND chip 10 includes a memory cell array 1. The memory cell array 1 includes plural bit lines extending in a column direction, plural word lines and source lines extending in a row direction, and plural memory cells selected by the bit line and the word line. The memory cell array 1 is described in detail later.

In the first embodiment, for example, data is read and written in units of called “page”. As used herein, the “page” means a set of memory cells selected by one word line. In the case that multi-bit data is stored in one memory cell, sometimes the page means a set of identical bits of each memory cell. However, in the first embodiment, for the latter, in the case of using two bits/cell, the page constructed with an upper-order bit and the page constructed with a lower-order bit are distinguished from each other while referred to as a “U (Upper) page” and an “L (Lower) page”, respectively.

The NAND chip 10 also includes a control unit that performs a read sequence and a write sequence. The read sequence is a series of pieces of processing of reading the data, and the write sequence is a series of pieces of processing of writing the data. The control unit includes a row decoder/word line driver 2a, a column decoder 2b, a page buffer 3, a row address register 5a and a column address register 5b, a logic control circuit 6, a sequence control circuit 7, a voltage generator 8, and an I/O buffer 9.

The row decoder/word line driver 2a drives the word line and a selection gate line (to be described) of the memory cell array 1. The page buffer 3 includes a sense amplifier circuit for one page and a data retaining circuit for one page. The one-page read data retained by the page buffer 3 is sequentially column-selected by the column decoder 2b, and is output to an external I/O terminal through the I/O buffer 9. The write data supplied to the external I/O terminal is selected by the column decoder 2b and loaded on the page buffer 3. The one-page write data is loaded on the page buffer 3. A row address signal and a column address signal are input through the I/O buffer 9, and transferred to the row decoder 2a and the column decoder 2b. The row address register 5a retains an erase block address in the case that the data is erased, and the row address register 5a retains a page address in the case that the data is read or written. A lead column address used to load the write data before the write sequence and a lead column address used in the read sequence are input to the column address register 5b. The column address register 5b retains the input column address until a write enable signal /WE or a read enable signal /RE is toggled on a certain condition.

The logic control circuit 6 controls input of a command or the address and input/output of the data based on control signals such as a chip enable signal /CE, a command enable signal CLE, an address latch enable signal ALE, a write enable signal /WE, and a read enable signal /RE. A read operation and a write operation are performed using the command. In response to the command, the sequence control circuit 7 performs read, write, or erase sequence control. The voltage generator 8 generates a certain voltage necessary for various operations under the control of the sequence control circuit 7.

The controller 11 controls the read sequence and the write sequence on the condition suitable for a present write state of the NAND chip 10. The read sequence and the write sequence can partially be controlled by the control unit of the NAND chip 10.

The memory cell array 1 of the nonvolatile semiconductor memory device of the first embodiment will be described below.

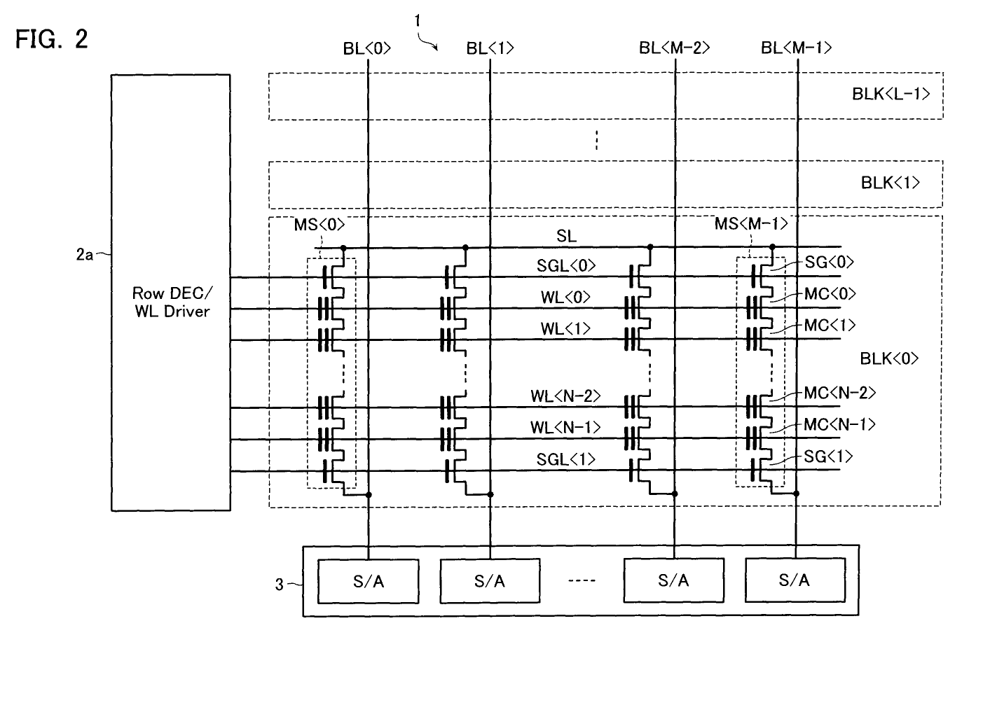

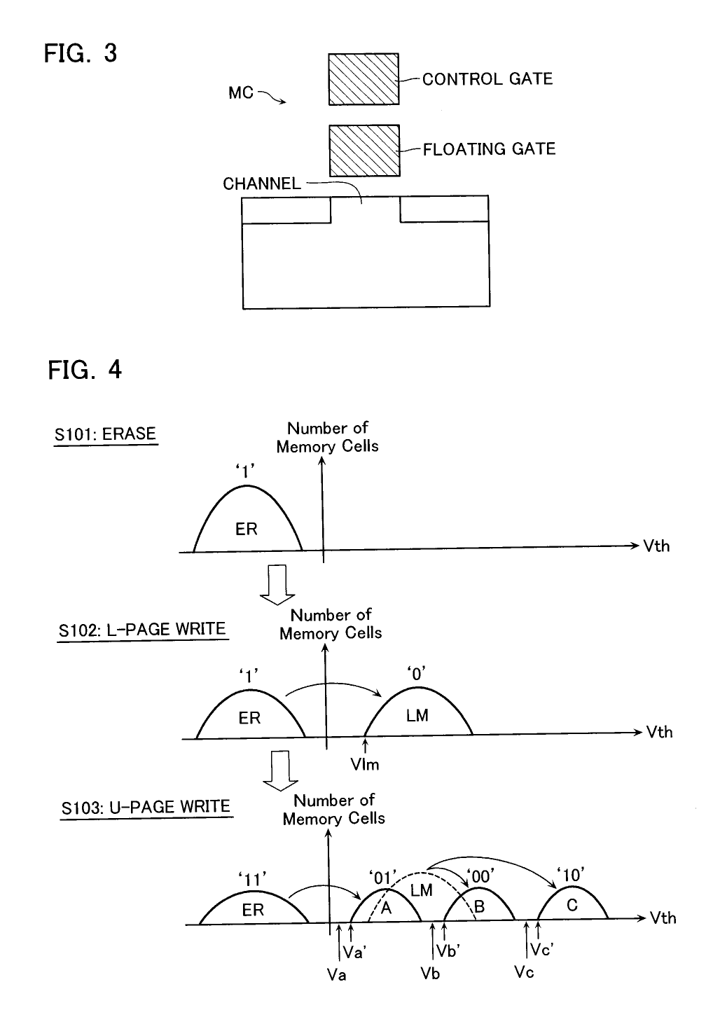

FIG. 2 is a circuit diagram illustrating the memory cell array of the nonvolatile semiconductor memory device of the first embodiment. FIG. 3 is a structural diagram illustrating the memory cell of the nonvolatile semiconductor memory device of the first embodiment.

The memory cell array 1 includes N word lines WL<0>to WL<N-1> extending in the row direction, selection gate lines SGL<0> and SGL<1> extending in the row direction, a source line SL extending in the row direction, M bit lines BL<0> to BL<M-1> extending in the column direction, and M memory strings MS<0> to MS<M-1> extending in the column direction. Each memory string MS includes N series-connected memory cells MC<0> MC<N-1> and select gate transistors SG<0> and SG <1> that are connected at both ends of the series-connected memory cells MC<0> MC<N-1>. Each memory cell MC includes a channel on a semiconductor substrate, a floating gate (charge accumulation layer) formed on the channel, and a transistor having a control gate formed on the floating gate.

A source of the select gate transistor SG<0> is connected to the source line SL. A drain of the select gate transistor SG<1> is connected to one of the bit lines BL<0> to BL<M-1>. The control gates of the memory cells MC<0> to MC<N-1> are connected to the word lines WL<0> to WL<N-1>. Gates of the select gate transistor SG<0> and SG<1> are connected to the selection gate lines SGL<0> and SGL<1>.

In the above configuration, M memory strings 4 arrayed in the row direction constitute one block BLK. The block BLK becomes a unit of collectively-erased data. The memory cell array 1 includes L blocks BLK<0> to BLK<L-1> arrayed in the column direction.

The word line WL and the selection gate line SGL are driven by the row decoder 2a. Each bit line BL is connected to a sense amplifier circuit S/A of the page buffer 3.

The write sequence of the first embodiment will be described below.

The case that the memory cell MC of two bits/cell is used will mainly be described below by way of example. However, it is noted that the first embodiment can also be applied to the memory cell in which at least three bits are stored. By way of example, threshold voltage distributions of the memory cell MC are referred to as an ER level, an A level, a B level, and a C level in the ascending order, and ‘11’ (first data), ‘01’ (second data), ‘00’ (third data), and ‘10’ (fourth data) are allocated to the threshold voltage distributions.

The following terms are used in the following description. A certain bit line is referred to as an “interested bit line”, a bit line adjacent to the interested bit line is referred to as an “adjacent bit line”, a certain memory cell belonging to a memory string between the interested bit line and a source line is referred to as an “interested cell”, other memory cells are referred to as “non-interested cells”, a memory cell belonging to the memory string between the adjacent bit line and the source line in the non-interested cells and being connected to a certain word line in common with the interested cell is referred to as an “adjacent cell”, a word line connected to the interested cell is referred to as an “interested word line”, other word lines are referred to as “non-interested word lines”, a memory string to which the interested cell belongs is referred to as an “interested string”, and other interested strings are referred to as “non-interested strings” in some cases.

FIG. 4 is a view illustrating a state of a change in threshold voltage distribution of the memory cell during the write sequence in the nonvolatile semiconductor memory device of the first embodiment.

At first, an erase step is performed in Step S101. In Step S101, the pieces of data of all the memory cell MC in the blocks BLK are collectively erased. Therefore, a threshold voltage Vth of all the memory cell MC in the block BLK transitions to the lowest ER level.

Then an L-page write step is performed in Step S102. In the L-page write step, the data is written in the L page based on the lower-order bit of the write data. In the case that the lower-order bit of the write data is ‘1’, the threshold voltage Vth of the memory cell MC is maintained at the ER level. In the case that the lower-order bit of the write data is ‘0’, the threshold voltage Vth of the memory cell MC transitions from the ER level to an LM level that is of an intermediate level of the A level and the B level.

Finally a U-page write step is performed in Step S103. In the U-page write step, the data is written in the U page based on the upper-order bit of the write data. In the case that the threshold voltage Vth of the memory cell MC is in the ER level, and in the case that the upper-order bit of the write data is ‘1’, the threshold voltage Vth of the memory cell MC is maintained at the ER level. In the case that the threshold voltage Vth of the memory cell MC is in the ER level, and in the case that the upper-order bit of the write data is ‘0’, the threshold voltage Vth of the memory cell MC transitions to the A level. On the other hand, In the case that the threshold voltage Vth of the memory cell MC is in the LM level, and in the case that the upper-order bit of the write data is ‘0’, the threshold voltage Vth of the memory cell MC transitions to the B level. In the case that the threshold voltage Vth of the memory cell MC is in the LM level, and in the case that the upper-order bit of the write data is ‘1’, the threshold voltage Vth of the memory cell MC transitions to the C level.

In FIG. 4, a reference voltage Va (first reference voltage) is located between the ER level that is of the lowest threshold voltage distribution and the A level adjacent to the ER level. A reference voltage Vc (second reference voltage) is located between the C level that is of the highest threshold voltage distribution and the B level adjacent to the C level.

Thus, the two write steps, namely, the L-page write step and the U-page write step are performed to write the 2-bit data in the memory cell MC. A write loop is repeatedly performed in each write step. Each write loop includes a program operation to perform the transition of the threshold voltage Vth of the memory cell MC and a verify operation to verify whether the threshold voltage Vth of the memory cell MC transitions to a desired value.

In the program operation, in the case that the threshold voltage Vth of the interested cell MC of the interested string MS transitions (in the case that a program of the interested cell MC is permitted), the select gate transistor SG<0> on the side of the source line SL is put into a non-conduction state, and the select gate transistor SG<1> on the side of the interested bit line BL is put into a conduction state. A ground voltage Vss (0 V) is applied to the interested bit line BL. Therefore, a channel voltage at the interested string MS becomes Vch=Vss. In this bias state, when a program voltage Vpgm (for example, about 20 V) is applied to the interested word line WL, a program pass voltage Vpps is applied to the non-interested word line WL, a large electric field is generated between the floating gate and the channel of the interested cell MC, and electrons are injected to the floating gate of the interested cell MC by a tunnel current. As a result, the threshold voltage Vth of the interested cell MC transitions onto the positive voltage side.

On the other hand, in the case that the threshold voltage Vth of the interested cell MC does not transition (in the case that the permission of the program of the interested cell MC is inhibited), the select gate transistor SG<0> on the side of the source line SL is put into the non-conduction state, and the select gate transistor SG<1> on the side of the interested bit line BL is put into the conduction state. A power supply voltage Vcc (for example, about 3.3 V) is applied to the interested bit line BL. Therefore, the channel of the interested string MS is preliminarily charged. When the program voltage Vpgm is applied to the interested word line WL while the program pass voltage Vpass is applied to the non-interested word line WL, a channel voltage Vch at the interested string MS is boosted to an inhibit voltage Vinh (for example, up to ˜5 V, and ‘˜’ means the floating state) by capacitive coupling of the control gate and the channel of the memory cell MC in the interested string MS. Therefore, electrons are inhibited from being injected to the floating gate of the interested cell MC.

The read sequence of the first embodiment will be described below. A read sequence of a comparative example will be described as a premise of the read sequence of the first embodiment.

As described above, in the first embodiment, for example, the four threshold voltage distributions are set, and the pieces of data ‘11’, ‘01’, ‘00’, and ‘10’ are allocated to the ER level, the A level, the B level, and the C level, respectively, that are of the threshold voltage distributions.

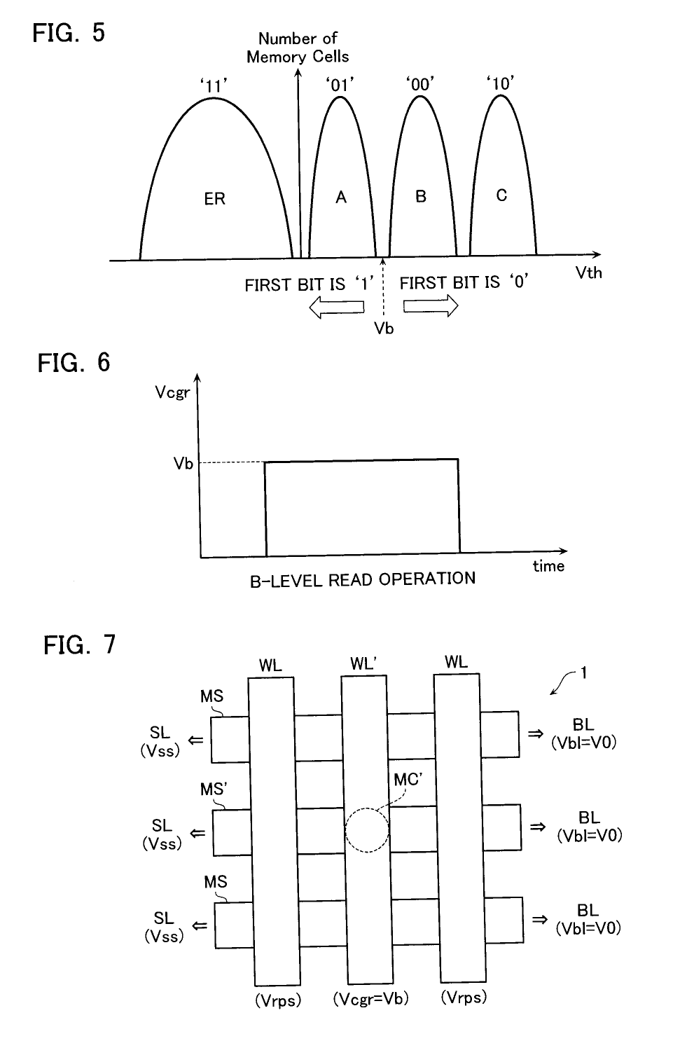

For the 2 bits/cell, the read sequence is performed by both or one of the L-page read step of reading the first bit of the data and the U-page read step of reading the second bit of the data. FIG. 5 is a view illustrating an L-page read step of the read sequence in a nonvolatile semiconductor memory device according to the comparative example. FIG. 6 is a view illustrating a state of a read voltage during the L-page read step of the read sequence in the nonvolatile semiconductor memory device of the comparative example. FIG. 7 is a view illustrating a bias state of the memory cell array during the L-page read step of the read sequence in the nonvolatile semiconductor memory device of the comparative example.

In other words, the L-page read step is a step of determining whether the first bit of the data is ‘1’ or ‘0’. As illustrated in FIG. 5, the determination whether the first bit of the data is ‘1’ or ‘0’ depends on whether the threshold voltage Vth of the memory cell MC is included in the ER level (‘11’) or the A level (‘01’) or whether the threshold voltage Vth of the memory cell MC is included in the B level (‘00’) or the C level (‘10’). That is, it is only necessary to detect whether the threshold voltage Vth of the memory cell MC is higher than a third reference voltage Vb (Vth>Vb). Hereinafter, sometimes a detection operation to detect whether the threshold voltage Vth of the memory cell MC is higher than the third reference voltage Vb is referred to as a “B-level read operation” (third read operation).

As illustrated in FIG. 7, in order to detect the threshold voltage Vth of the interested cell MC′, the ground voltage Vss (for example, 0 V) is previously applied to the source line SL, and a certain bit line voltage Vbl=V0 (for example, 0.25 V) is previously applied to all the bit lines BL. Then reference voltages Vcgr=Va, Vb, or Vc each of which is set between the threshold voltage distributions is applied to the interested word line WL′, and a read pass voltage Vrps (for example, about 6 V) higher than an upper skirt of the C level is applied to the non-interested word line WL. For the L-page write step, the reference voltage Vcgr=Vb is applied to the interested word line WL as illustrated in FIGS. 6 and 7. In this bias state, unless a cell current is not passed through the interested string MS′, it is found that the threshold voltage Vth of the interested cell MC′ is higher than the third reference voltage Vb. On the other hand, when the cell current is passed through the interested string MS′, it is found that the threshold voltage Vth of the interested cell MC′ is not higher than the third reference voltage Vb.

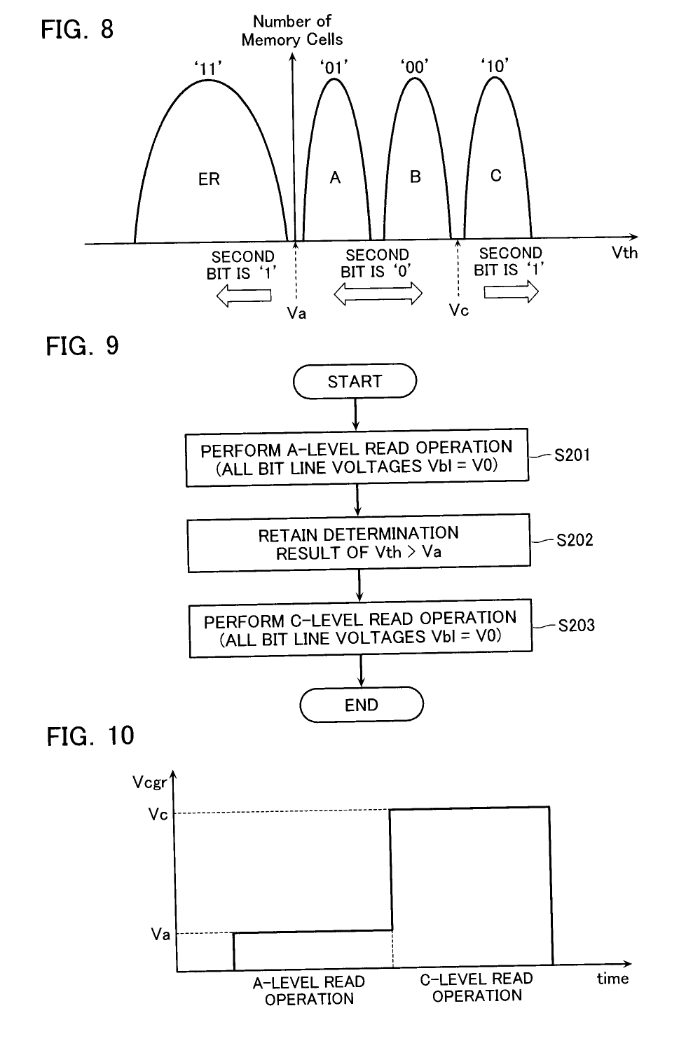

FIG. 8 is a view illustrating the U-page read step of the read sequence in the nonvolatile semiconductor memory device of the comparative example.

In other words, the U-page read step is a step of determining whether the second bit of the data is ‘1’ or ‘0’. As illustrated in FIG. 8, the determination whether the second bit of the data is ‘1’ or ‘0’ depends on whether the threshold voltage Vth of the memory cell MC is included in the ER level or the C level or whether the threshold voltage Vth of the memory cell MC is included in the A level or the B level. That is, it is only necessary to detect whether the threshold voltage Vth of the memory cell MC is higher than the first reference voltage Va and is smaller than the second reference voltage Vc (Va<Vth<Vc). Therefore, in the U-page read step, unlike the L-page read step, it is necessary to detect whether the threshold voltage Vth of the memory cell MC is smaller than the second reference voltage Vc (Vth<Vc) while whether the threshold voltage Vth is higher than the first reference voltage Va (Vth>Va) is detected. Hereinafter, sometimes a detection operation to detect whether the threshold voltage Vth of the memory cell MC is higher than the first reference voltage Va is referred to as an “A-level read operation” (second read operation). Sometimes a detection operation to detect whether the threshold voltage Vth of the memory cell MC is higher than the second reference voltage Vc is referred to as an “C-level read operation” (first read operation).

FIG. 9 is a flowchart illustrating the U-page read step of the read sequence in the nonvolatile semiconductor memory device of the comparative example, and FIG. 10 is a view illustrating the state of the read voltage during the U-page read step of the read sequence in the nonvolatile semiconductor memory device of the comparative example.

At first the A-level read operation is performed in Step S201. That is, as illustrated in FIG. 10, while the bit line voltage Vbl=V0 is applied to all the bit lines BL, the reference voltage Vcgr=Va (first reference voltage) is applied to the interested word line WL to detect that the first threshold voltage Vth of the interested cell MC is higher than the first reference voltage Va (Vth>Va).

Then, in Step S202, a determination result of the threshold voltage Vth of the interested cell MC in Step S201 is retained in, for example, a latch circuit of the page buffer 3.

Then the C-level read operation is performed in Step S203. That is, as illustrated in FIG. 10, the bit line voltage Vbl=V0 is applied to all the bit lines BL, while the reference voltage Vcgr=Vc (second reference voltage) is applied to the interested word line WL to detect that the first threshold voltage Vth of the interested cell MC is higher than the second reference voltage Vc (Vth>Vc).

Finally, whether the second bit of the storage data of the interested cell MC is ‘1’ or ‘0’ is determined based on the detection results in Steps S201 and S203.

The verify operation in the write sequence is identical to that in the read operation except that verify voltages Vvrf=Va′, Vb′, and Vc′ each of which indicates a lower limit of the threshold voltage distribution is used instead of the reference voltages Vcgr.

For the read sequence of the comparative example, possibly the following problem is generated.

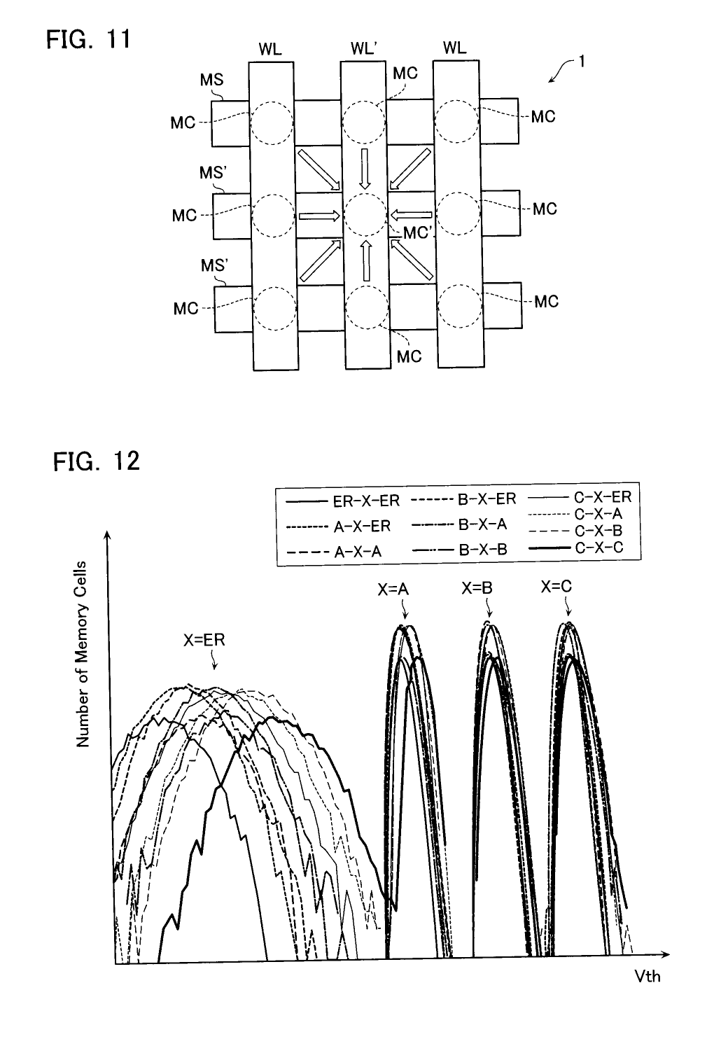

FIG. 11 is a view illustrating an interference effect generated between the memory cells adjacent to each other in the nonvolatile semiconductor memory device of the comparative example. As indicated by outlined arrows in FIG. 11, the memory cells MC around the interested cell MC′ have a parasitic gate effect and a parasitic capacitance effect on the interested cell MC′. The interference effect generates the transition of the threshold voltage Vth of the interested cell MC′ to cause a malfunction. The interference effect increases with decreasing memory cell array 1.

FIG. 12 is a view illustrating the state of the threshold voltage distribution of the memory cell after the write sequence of the nonvolatile semiconductor memory device of the comparative example. FIG. 12 illustrates the threshold voltage distribution while the threshold voltage distribution is exploded in each combination of the threshold voltage Vth of the adjacent cell MC. Hereinafter, in FIG. 12 and the following description, assuming that an X1 level (X is one of ER to C) is the threshold voltage of the interested cell while an X2 level and an X3 level are the threshold voltage of the adjacent cells, sometimes a combination of the threshold voltages of the memory cell is referred to as “X2-X1-X3”. In this case, sometimes the interested cell and the adjacent cell are referred to as an “X2-X1-X3 interested cell” and an “X2-X1-X3 adjacent cell”.

For example, in the case that attention is paid to the ER level, it is found that the different threshold voltage distribution is exerted according to the threshold voltage Vth of each adjacent cell even if the identical ER level is set to different interested cells. Specifically, the threshold voltage Vth of the ER-X-ER interested cell is distributed low and the threshold voltage Vth of the C-X-C interested cell is distributed high. Therefore, it is found that many threshold voltages Vth of the C-X-C interested cells are distributed around the upper skirt of the ER level. This is because the program of the C level is performed to the adjacent cell after the interested cell transitions to the ER level by the erase step. The program of the C level is one that causes the threshold voltage Vth of the adjacent cell to transition maximally, and the interference effect on the interested cell of the program of the C level is larger than that of other programs. As a result, the threshold voltage Vth of the C-X-C interested cell transitions to the higher level compared with other cases. The same holds true for the case that attention is paid to the A to C levels, and a margin between the threshold voltage distributions adjacent to each other is narrowed.

When an influence of the interference effect of the adjacent cell increases, the upper skirt of the ER level is higher than the reference voltage Va, and eventually overlaps the lower skirt of the A level. In the case that the ER level overlaps the A level, in the read sequence of the comparative example, the interested cell that is originally set to the ER level is mistakenly read as the data set to the A level.

Therefore, in order to solve the problem, the following read sequence is performed in the first embodiment. In the read sequence of the first embodiment, the generation of the memory cell distributed in the upper skirt of the ER level can be constrained without lowering the lower skirt of the A level. As a result, the margin of the threshold voltage is spread between the ER level and the A level, so that data reliability of the nonvolatile semiconductor memory device can be improved.

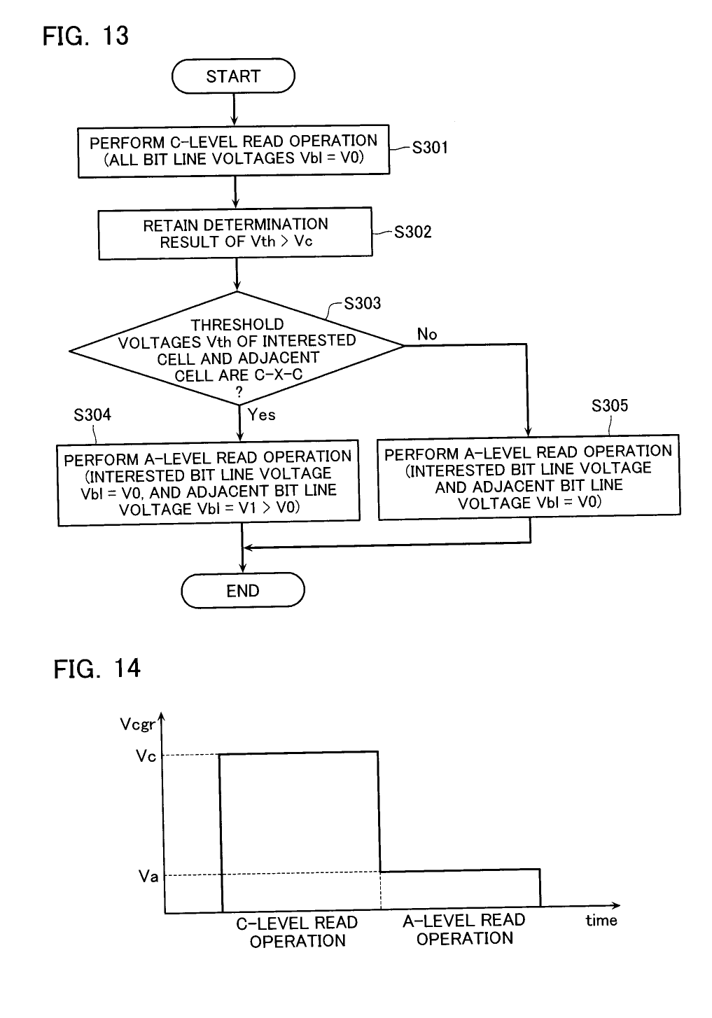

FIG. 13 is a flowchart illustrating the U-page read step of the read sequence in the nonvolatile semiconductor memory device of the first embodiment. FIG. 14 is a view illustrating the state of the read voltage during the U-page read step of the read sequence in the nonvolatile semiconductor memory device of the first embodiment. FIG. 15 is a view illustrating the bias state of the memory cell array during the U-page read step of the read sequence in the nonvolatile semiconductor memory device of the first embodiment.

At first the C-level read operation (first read operation) is performed in Step S301. That is, as illustrated in FIG. 14, while the bit line voltage Vbl=V0 (for example, 0.25 V) (first bit line voltage) is applied to all the bit lines BL, the reference voltage Vcgr=Vc (second reference voltage) is applied to the interested word line WL to detect that the threshold voltage Vth of the memory cell MC is higher than the second reference voltage Vc (Vth>Vc). In other words, whether the storage data of the memory cell MC is ‘10’ is determined by the C-level read operation.

Then, in Step S302, the determination result of the threshold voltage Vth of the memory cell MC in Step S301 is retained in, for example, the latch circuit of the page buffer 3.

Then, whether the threshold voltages Vth of the three adjacent memory cells MC are C-X-C is determined in Step S303. The processing goes to Step S304 when the threshold voltages Vth of the three adjacent memory cells MC are C-X-C, and the processing goes to Step S305 when the threshold voltages Vth of the three adjacent memory cells MC are not C-X-C.

Then the A-level read operation (second read operation) is performed in Steps S304 and S305.

In Step S304, the A-level read operation is performed to the C-X-C interested cell MC′. That is, while the bit line voltage Vbl=V1 (for example, 0.75 V) (second bit line voltage) higher than the voltage V0 is applied to the adjacent bit line BL as illustrated in FIG. 15, the reference voltage Vcgr=Va (first reference voltage) is applied to the interested word line WL′ to detect that the threshold voltage Vth of the interested cell MC′ is higher than the first reference voltage Va (Vth>Va) as illustrated in FIG. 14. In other words, whether the storage data of the memory cell MC is ‘11’ is determined by the A-level read operation.

On the other hand, in Step S305, the A-level read operation is performed to the interested cell MC′ except the C-X-C interested cell MC′. That is, as illustrated in FIG. 14, while the bit line voltage V0 is applied to the adjacent bit line BL, the reference voltage Vcgr=Va (first reference voltage) is applied to the interested word line WL′ to detect that the threshold voltage Vth of the interested cell MC′ is higher than the first reference voltage Va (Vth>Va).

Thus, the U-page read step in the read sequence of the first embodiment is described. In the case that the U-page read step and the L-page read step are continuously performed, the U-page read step may be performed before or after the L-page read step similarly to the comparative example.

For the read sequence of the first embodiment, unlike the comparative example, whether the threshold voltage Vth of the interested cell MC′ is higher than the first reference voltage Va (Vth>Va) is detected while the memory cell array 1 is put into the bias state in FIG. 15.

Thus, compared with the case that bit line voltage Vbl=V0 is applied to the adjacent bit line BL, the voltage Vth of the interested cell MC′ can be read low by applying the bit line voltage Vbl=V1 higher than the voltage V0 to the adjacent bit line BL.

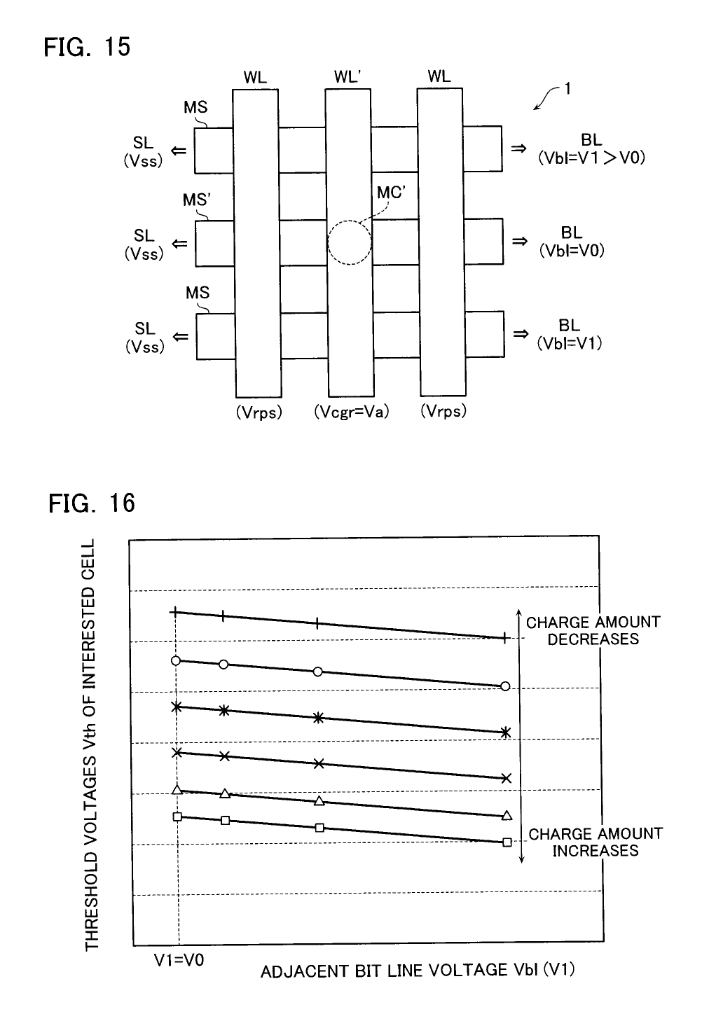

FIG. 16 is a graph illustrating a relationship between the bit line voltage at the adjacent bit line and the threshold voltage of the interested cell in the nonvolatile semiconductor memory device. In FIG. 16, a horizontal axis indicates the bit line voltage Vbl at the adjacent bit line BL, and a vertical axis indicates the threshold voltage Vth of the interested cell MC′. Each charge amount set to the floating gate of the interested cell MC′ is illustrated in the graph in FIG. 16.

As can be seen from FIG. 16, the threshold voltage Vth of the interested cell MC decreases monotonously with respect to the bit line voltage Vbl, and a decreasing tendency of the threshold voltage Vth is independent of the charge amount in the floating gate. In the read sequence of the first embodiment, using the characteristic in FIG. 16, the threshold voltage Vth of the C-ER-C interested cell MC′ constituting the upper skirt of the ER level can be read low while the threshold voltage Vth of the memory cell MC constituting the lower skirt of the A level is retained.

However, for the use of the read sequence of the first embodiment, it is noted that the voltage V1 used as the bit line voltage Vbl has an optimum value.

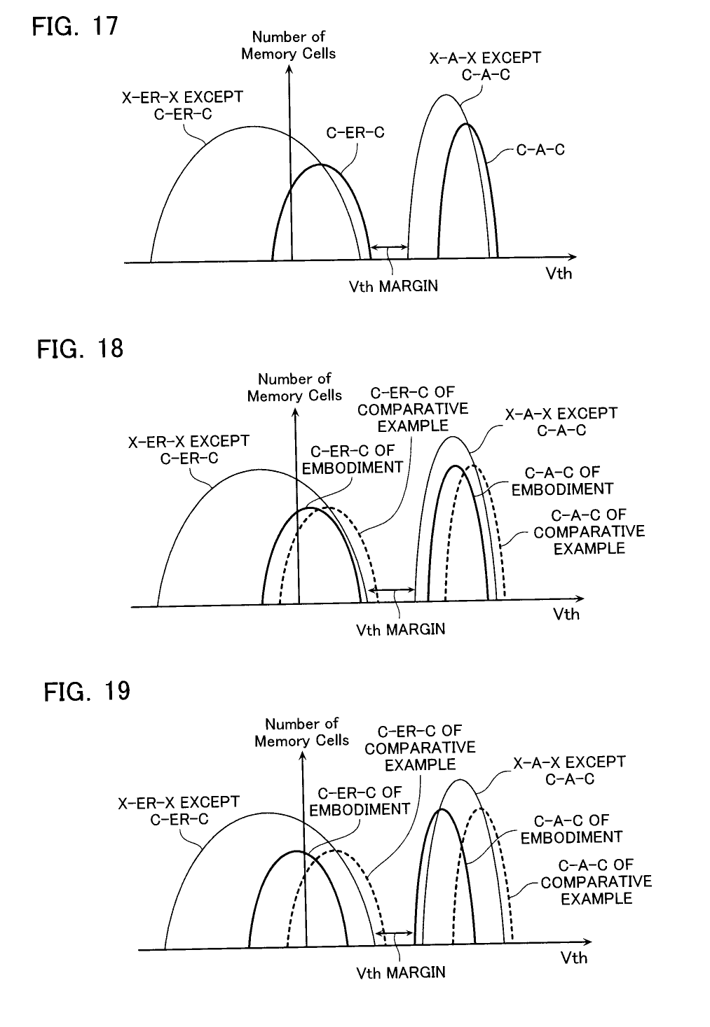

FIG. 17 is a view illustrating the state of the threshold voltage distribution of the memory cell during the read sequence in the nonvolatile semiconductor memory device of the comparative example. FIGS. 18 and 19 are views illustrating the state of the threshold voltage distribution of the memory cell during the read sequence in the nonvolatile semiconductor memory device of the first embodiment.

FIG. 17 illustrates the case of the bit line voltage Vbl=V0, namely, the case that the bit line voltage Vbl=V1 is lower than the optimum value. In this case, it is difficult that the threshold voltage Vth of the C-ER-C interested cell is read sufficiently low. Therefore, because the upper skirt of the whole ER level becomes insufficiently low, the margin is insufficiently spread between the ER level and the A level.

FIG. 18 illustrates the case that the bit line voltage Vbl=V1 is the optimum value. In this case, the threshold voltage Vth of the C-ER-C interested cell is read sufficiently low. Therefore, because the upper skirt of the whole ER level becomes sufficiently low, the margin is sufficiently spread between the ER level and the A level compared with the comparative example.

FIG. 19 illustrates the case that the bit line voltage Vbl=V1 is excessively high. In this case, the threshold voltage Vth of the C-ER-C interested cell is read sufficiently low. However, the effect to reduce the upper skirt of the whole ER level reaches a limit due to existence of other interested cells. Additionally, the threshold voltage Vth of the C-A-C interested cell is read excessively low, and the threshold voltage distribution of the C-A-C interested cell is excessively lowered. Therefore, the lower skirt of the whole A level is read low. As a result, the margin is narrowed between the ER level and the A level compared with the comparative example.

Thus, desirably the voltage V1 used as the bit line voltage Vbl is increased within a range where the lower skirt of the threshold voltage distribution of the C-A-C interested cell is not lower than the lower skirt of the threshold voltage distribution of the X-A-X interested cell except the C-A-C interested cell. Because the increase in bit line voltage Vbl leads to an increase in leakage current during the read sequence, it is noted that the voltage V1 is not excessively increased.

An advantageous effect of the read sequence of the first embodiment will be described below.

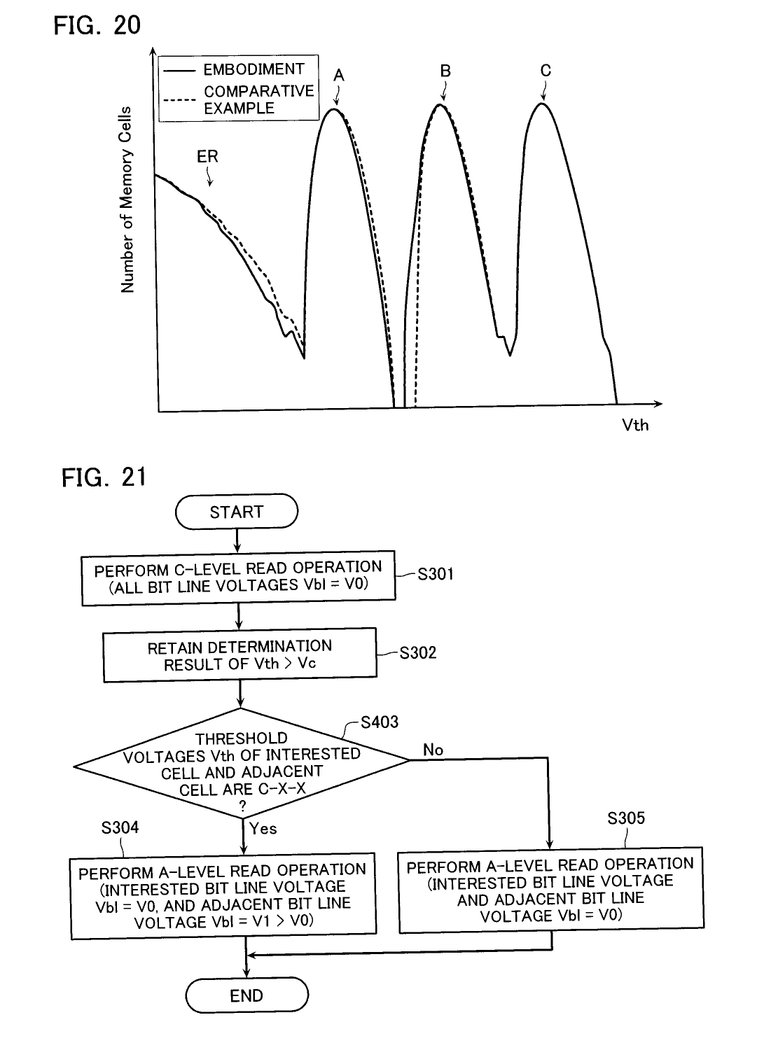

FIG. 20 is a view illustrating the state of the threshold voltage distribution of the memory cell during the read sequence in the nonvolatile semiconductor memory device of the first embodiment. FIG. 20 also illustrates the case of the comparative example in addition to the case of the first embodiment.

As can be seen from FIG. 20, compared with the comparative example, the spread of the upper skirt of the ER level is constrained, and the margin of the threshold voltage Vth expands between the ER level and the A level. On the other hand, the margin of the threshold voltage Vth narrows between the A level and the B level. This is because the threshold voltage Vth of the C-B-C interested cell is read low to bring the lower skirt of the B level close to the upper skirt of the A level. However, because the U-page read step is performed in order to determine whether the threshold voltage Vth of the memory cell is higher than the first reference voltage Va (Vth>Va) and is higher than the second reference voltage Vc (Vth>Vc), there is no problem even if the margin of the threshold voltage Vth narrows between the A level and the B level.

As described above, according to the first embodiment, the threshold voltage of the memory cell constituting the upper skirt of the ER level is read low, so that the margin of the threshold voltage can be expanded between the ER level and the A level. As a result, the nonvolatile semiconductor memory device having the high data reliability and the method for operating the nonvolatile semiconductor memory device can be provided.

### Second Embodiment

Modifications of the first embodiment will be described below as a second embodiment.

FIG. 21 is a flowchart illustrating a read sequence in a nonvolatile semiconductor memory device according to the second embodiment

The modification in FIG. 21 differs from the first embodiment in the determination condition in Step S303. In the modification of FIG. 21, Step S403 branches into Steps S304 and S305 based on whether the threshold voltage Vth of the three adjacent memory cells MC is C-X-X, namely, whether at least one of the two adjacent cells MC of the interested cell is in the C level.

As illustrated in FIG. 12, the upper skirt of the ER level is considerably influenced by not only the threshold voltage distribution of the C-ER-C interested cell but also the threshold voltage distribution of C-ER-ER/A/B. On the other hand, in the modification of FIG. 21, the upper skirt of the ER level can be lowered compared with the first embodiment.

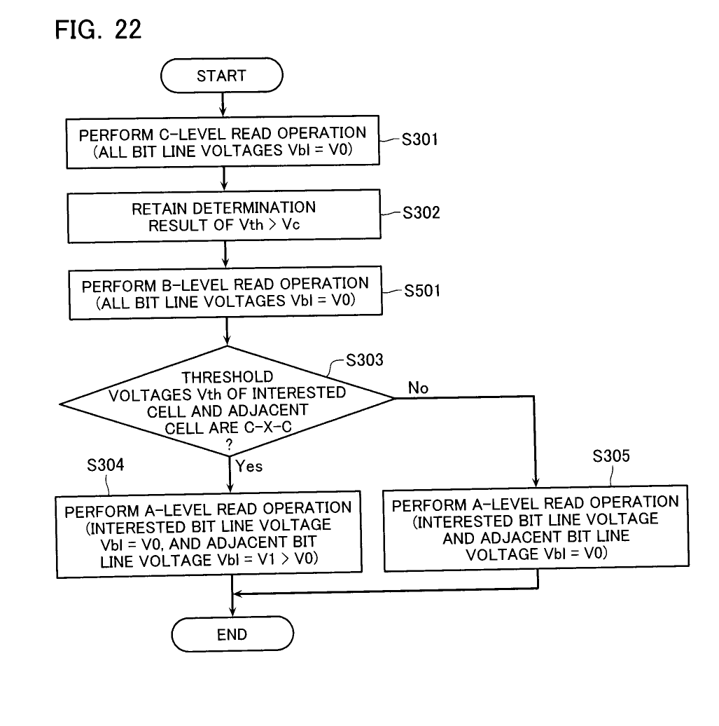

FIG. 22 is a flowchart illustrating another read sequence in the nonvolatile semiconductor memory device of the second embodiment.

The modification in FIG. 22 differs from the first embodiment in determination order of the threshold voltage of the memory cell. In the modification of FIG. 22, the C-level read operation (Step S301), the B-level read operation (Step S501), and the A-level read operation (Steps S304 and S305) are sequentially performed. The B-level read operation in S501 is performed by applying the reference voltage Vcgr=Vb to the interested word line WL while the bit line voltage Vbl=V0 is applied to all the bit lines BL.

In order to obtain the advantageous effect similar to that of the first embodiment, it is necessary to perform the C-level read operation before the A-level read operation. Therefore, unlike the first embodiment, it is not always necessary that the U-page read step is continuously performed, but the B-level read operation can also be performed between the C-level read operation and the A-level read operation.

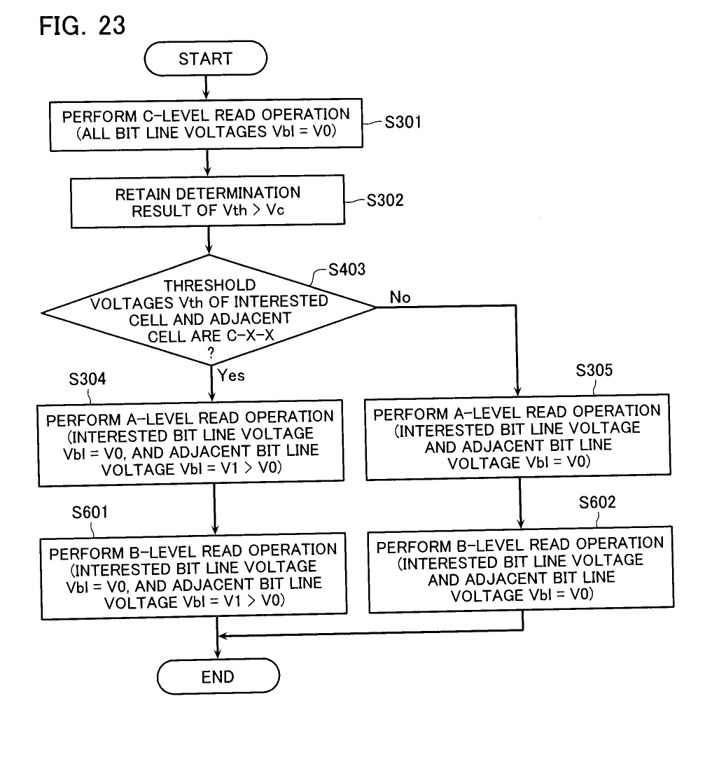

FIG. 23 is a flowchart illustrating still another read sequence in the nonvolatile semiconductor memory device of the second embodiment.

In the modification of FIG. 23, the B-level read operation is performed after the A-level read operation. In the modification of FIG. 23, the B-level operation is performed in Steps S601 and S602 by applying the voltage that is identical to the bit line voltage Vbl applied to the adjacent bit line BL during the A-level read operation in Steps S304 and S305.

In the modification of FIG. 23, necessity of bit line voltage switching control is eliminated during the transition from the A-level read operation to the C-level read operation.

The first embodiment and the modifications of the first embodiment described as the second embodiment can also be applied to the nonvolatile semiconductor memory device provided with a memory cell, such as an 8 bits/cell and a 16 bits/cell, in which at least 3 bits are stored.

[Others]

The embodiments of the present invention are described above. However, the embodiments are described only by way of example, and the embodiments are not intended to restrict the scope of the invention. Various modes of the embodiments can be made, and various omission, replacements, and changes can be made without departing from the scope of the invention. The embodiments and the modifications are included in the scope or summary of the invention and also included in the range equivalent to the inventions described in the claims.

What is claimed is:

1. A nonvolatile semiconductor memory device comprising:
a memory cell array including a plurality of bit lines, a plurality of word lines and a source line that intersect the plurality of bit lines, and a plurality of memory strings that are provided between the bit line and the source line, each of the plurality of memory strings including a plurality of series-connected memory cells each of which is connected to the word line; and
a control unit that performs a write sequence writing data to the memory cell and a read sequence reading data from the memory cell, wherein,
assuming that the certain bit line is an interested bit line, that the bit line adjacent to the interested bit line is an adjacent bit line, that the certain memory cell belonging to the memory string between the interested bit line and the source line is an interested cell, and that the memory cell belonging to the memory string between the adjacent bit line and the source line and being commonly connected to the interested cell and the certain word line is an adjacent cell,
the control unit causes a threshold voltage of the memory cell to transition to a desired value higher than a first reference voltage after causing the threshold voltage to transition to a value lower than the first reference voltage during the write sequence,
the control unit, during the read sequence performed to the interested cell,
performs a first read operation to detect that the threshold voltage of the adjacent cell is higher than a second reference voltage higher than the first reference voltage,
performs a second read operation to detect that the threshold voltage of the interested cell is higher than the first reference voltage while applying a first bit line voltage to the adjacent bit line when threshold voltages of the adjacent cells are lower than the second reference voltage after the first read operation, and
performs the second read operation to detect that the threshold voltage of the interested cell is higher than the first reference voltage while applying a second bit line voltage higher than the first bit line voltage to the adjacent bit line when the threshold voltages of the adjacent cells are higher than the second reference voltage after the first read operation.

2. The nonvolatile semiconductor memory device according to claim 1, wherein the control unit applies the second bit line voltage to the adjacent bit line when the threshold voltage of one of the adjacent cells is higher than the second reference voltage during the second read operation.

3. The nonvolatile semiconductor memory device according to claim 1, wherein the control unit performs a third read operation to detect that the threshold voltage of the interested cell is higher than the first reference voltage and is lower than the second reference voltage during the read sequence performed to the interested cell.

4. The nonvolatile semiconductor memory device according to claim 2, wherein the control unit applies the first bit line voltage to the adjacent bit line irrespective of the threshold voltage of the adjacent cell during the third read operation.

5. The nonvolatile semiconductor memory device according to claim 2, wherein the control unit applies a voltage equal to a voltage which is applied to the adjacent bit line during the second read operation, to the adjacent bit line during the third read operation, when the third read operation is performed after the second read operation.

6. The nonvolatile semiconductor memory device according to claim 1, wherein
the memory cell stores a plurality of pieces of data using a plurality of threshold voltage distributions, and
the first reference voltage has a value between a lowest threshold voltage distribution and a threshold voltage distribution adjacent to the lowest threshold voltage distribution in the plurality of threshold voltage distributions.

7. The nonvolatile semiconductor memory device according to claim 1, wherein
the memory cell stores a plurality of pieces of data using a plurality of threshold voltage distributions, and
the second reference voltage has a value between a highest threshold voltage distribution and a threshold voltage distribution adjacent to the highest threshold voltage distribution in the plurality of threshold voltage distributions.

8. A nonvolatile semiconductor memory device comprising:
a memory cell array including a plurality of bit lines, a plurality of word lines and a source line that intersect the plurality of bit lines, and a plurality of memory strings that are provided between the bit line and the source line, each of the plurality of memory strings including a plurality of series-connected memory cells each of which is connected to the word line; and
a control unit that performs a write sequence writing data to the memory cell and a read sequence reading data from the memory cell, wherein,
assuming that the certain bit line is an interested bit line, that the bit line adjacent to the interested bit line is an adjacent bit line, that the certain memory cell belonging to the memory string between the interested bit line and the source line is an interested cell, and that the memory cell belonging to the memory string between the adjacent bit line and the source line and being commonly connected to the interested cell and the certain word line is an adjacent cell,
the memory cell stores first to fourth pieces of 2-bit data,
the control unit programs desired data after programming the first data in the memory cell during the write sequence,
the control unit, during the read sequence performed to the interested cell,
performs a first read operation to determine that storage data of the adjacent cell is the fourth data,
performs a second read operation to determine that storage data of the interested cell is the first data while applying a first bit line voltage to the adjacent bit line when both pieces of storage data of the adjacent cells are not the fourth data, and
performs the second read operation to determine that the storage data of the interested cell is the first data while applying a second bit line voltage higher than the first bit line voltage to the adjacent bit line when both the pieces of storage data of the adjacent cells are the fourth data.

9. The nonvolatile semiconductor memory device according to claim 8, wherein the control unit performs a third read operation to determine that the storage data of the interested cell is the third or fourth data during the read sequence performed to the interested cell.

10. The nonvolatile semiconductor memory device according to claim 8, wherein the control unit applies the first bit line voltage to the adjacent bit line irrespective of the storage data of the adjacent cell during the third read operation.

11. The nonvolatile semiconductor memory device according to claim 8, wherein the control unit applies a voltage equal to a voltage which is applied to the adjacent bit line during the second read operation, to the adjacent bit line during the third read operation, when the third read operation is performed after the second read operation.

12. The nonvolatile semiconductor memory device according to claim 8, wherein the memory cell stores the first to fourth pieces of data while associating the first to fourth pieces of data with sequentially-heightened first to fourth threshold voltage distributions.

13. The nonvolatile semiconductor memory device according to claim 8, wherein the first and second pieces of data differ from the third and fourth pieces of data in a first bit of the data, and the first and fourth pieces of data differ from the second and third pieces of data in a second bit of the data.

14. A method for operating a nonvolatile semiconductor memory device including:
a memory cell array including a plurality of bit lines, a plurality of word lines and a source line that intersect the plurality of bit lines, and a plurality of memory strings that are provided between the bit line and the source line, each of the plurality of memory strings including a plurality of series-connected memory cells each of which is connected to the word line; and
a control unit that performs a write sequence writing data in the memory cell and a read sequence reading data from the memory cell,
assuming that the certain bit line is an interested bit line, that the bit line adjacent to the interested bit line is an adjacent bit line, that the certain memory cell belonging to the memory string between the interested bit line and the source line is an interested cell, and that the memory cell belonging to the memory string between the adjacent bit line and the source line and being commonly connected to the interested cell and the certain word line is an adjacent cell,
the control unit causing a threshold voltage of the memory cell to transition to a desired value higher than a first reference voltage after causing the threshold voltage of the memory cell to transition to a value lower than the first reference voltage during the write sequence, wherein,
during the read sequence to the interested cell,
a first read operation to detect that the threshold voltage of the adjacent cell is higher than a second reference voltage higher than the first reference voltage is performed,
a second read operation to detect that the threshold voltage of the interested cell is higher than the first reference voltage is performed while a first bit line voltage is applied to the adjacent bit line when threshold voltages of the adjacent cells are lower than the second reference voltage after the first reference voltage, and
a second read operation to detect that the threshold voltage of the interested cell is higher than the first reference voltage is performed while a second bit line voltage higher than the first bit line voltage is applied to the adjacent bit line when threshold voltages of the adjacent cells are higher than the second reference voltage after the first reference voltage,
by the control unit.

15. The nonvolatile semiconductor memory device operation method according to claim 14, wherein the control unit applies the second bit line voltage to the adjacent bit line when the threshold voltage of one of the adjacent cells is higher than the second reference voltage during the second read operation.

16. The nonvolatile semiconductor memory device operation method according to claim 14, wherein the control unit performs a third read operation to detect that the threshold voltage of the interested cell is higher than the first reference voltage and is lower than the second reference voltage during the read sequence performed to the interested cell.

17. The nonvolatile semiconductor memory device operation method according to claim 15, wherein the control unit applies the first bit line voltage to the adjacent bit line irrespective of the threshold voltage of the adjacent cell during the third read operation.

18. The nonvolatile semiconductor memory device operation method according to claim 15, wherein the control unit applies a voltage equal to a voltage which is applied to the adjacent bit line during the second read operation, to the adjacent bit line during the third read operation, when the third read operation is performed after the second read operation.

19. The nonvolatile semiconductor memory device operation method according to claim 14, wherein
the memory cell stores a plurality of pieces of data using a plurality of threshold voltage distributions, and
the first reference voltage has a value between a lowest threshold voltage distribution and a threshold voltage distribution adjacent to the lowest threshold voltage distribution in the plurality of threshold voltage distributions.

20. The nonvolatile semiconductor memory device operation method according to claim 14, wherein
the memory cell stores a plurality of pieces of data using a plurality of threshold voltage distributions, and
the first reference voltage has a value between a highest threshold voltage distribution and a threshold voltage distribution adjacent to the highest threshold voltage distribution in the plurality of threshold voltage distributions.
